(19) United States
(12) Patent Application Publication
(10) Pub. No.: US 2025/0300432 A1
(43) Pub. Date: Sep. 25, 2025

(54) OPTICAL ELEMENTS AND SURFACE EMITTING LASERS

(71) Applicant: KABUSHIKI KAISHA TOSHIBA, Tokyo (JP)

(72) Inventors: Shinji SAITO, Yokohama Kanagawa (JP); Tsutomu KAKUNO, Fujisawa Kanagawa (JP); Kei KANEKO, Yokohama Kanagawa (JP); Rei HASHIMOTO, Edogawa Tokyo (JP); Shinji OOKUMA, Yokohama Kanagawa (JP); Tetsuya MIYAGAWA, Yokohama Kanagawa (JP)

(21) Appl. No.: 18/986,224

(22) Filed: Dec. 18, 2024

(30) Foreign Application Priority Data
Mar. 22, 2024 (JP) 2024-046002

(51) Int. Cl. H01S 5/18; H01S 5/062; H01S 5/11; H01S 5/34

(52) U.S. Cl. CPC H01S 5/18; H01S 5/0624; H01S 5/11; H01S 5/3402

(57) ABSTRACT

According to one embodiment, an optical element includes a first member. The first member includes a first region along a first plane. The first region includes a plurality of first structures. The plurality of first structures are arranged along a first direction at a first pitch and along a second direction at a second pitch. The first direction is along the first plane. The second direction is along the first plane and crosses the first direction. The first pitch is longer than the second pitch. A first length of the first region along the first direction is longer than a second length of the first region along the second direction.

### CROSS-REFERENCE TO RELATED APPLICATIONS

This application is based upon and claims the benefit of priority from Japanese Patent Application No. 2024-046002, filed on Mar. 22, 2024; the entire contents of which are incorporated herein by reference.

### FIELD

Embodiments described herein relate generally to an optical element and a surface emitting laser.

### BACKGROUND

For example, optical elements such as photonic crystals are used in surface emitting lasers. It is desired to improve the characteristics of optical elements.

### BRIEF DESCRIPTION OF THE DRAWINGS

FIG. 1 is a schematic plan view illustrating an optical element according to a first embodiment;

FIG. 2 is a schematic plan view illustrating a part of the optical element according to the first embodiment;

FIGS. 3A and 3B are schematic cross-sectional views illustrating the optical element according to the first embodiment;

FIGS. 4A to 4D are schematic diagrams illustrating the characteristics of the optical element;

FIGS. 5A and 5B are schematic cross-sectional views illustrating an optical element according to the first embodiment; and

FIG. 6 is a schematic cross-sectional view illustrating a surface emitting laser according to a second embodiment.

### DETAILED DESCRIPTION

According to one embodiment, an optical element includes a first member. The first member includes a first region along a first plane. The first region includes a plurality of first structures. The plurality of first structures are arranged along a first direction at a first pitch and along a second direction at a second pitch. The first direction is along the first plane. The second direction is along the first plane and crosses the first direction. The first pitch is longer than the second pitch. A first length of the first region along the first direction is longer than a second length of the first region along the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

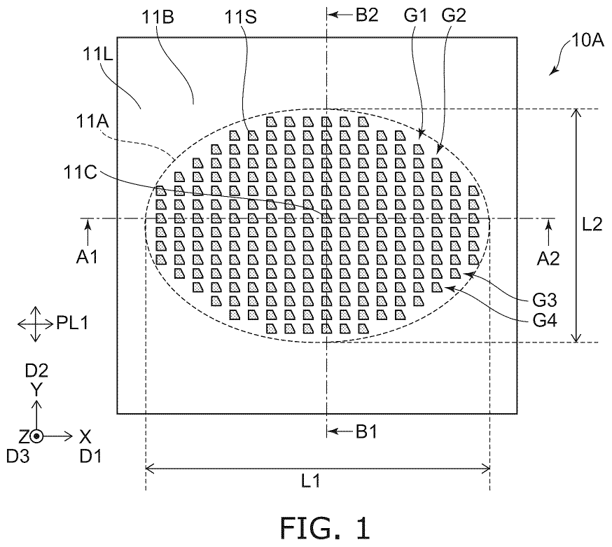

FIG. 1 is a schematic plan view illustrating an optical element according to a first embodiment.

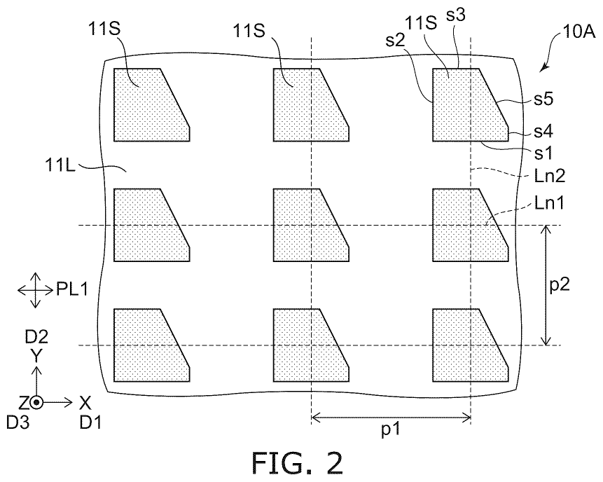

FIG. 2 is a schematic plan view illustrating a part of the optical element according to the first embodiment.

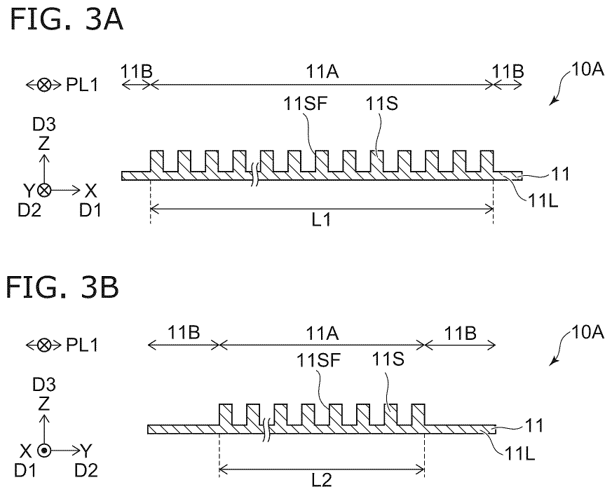

FIGS. 3A and 3B are schematic cross-sectional views illustrating the optical element according to the first embodiment.

FIG. 3A corresponds to a cross section taken along the line A1-A2 in FIG. 1. FIG. 3B corresponds to a cross section taken along the line B1-B2 in FIG. 1.

As shown in FIG. 1, an optical element 10A according to the embodiment includes a first member 11. The first member 11 includes a first region 11A. The first region 11A extends along a first plane PL1.

The first plane PL1 is, for example, substantially parallel to an X-Y plane. A first direction D1 and a second direction D2 are along the first plane PL1. The first direction D1 may be, for example, a X-axis direction.

One direction perpendicular to the X-axis direction is defined as a Y-axis direction. A direction perpendicular to the X-axis direction and the Y-axis direction is defined as a Z-axis direction. The Z-axis direction is perpendicular to the first plane PL1. In one example, the second direction D2 is the Y-axis direction.

As shown in FIG. 1, the first region 11A includes a plurality of first structures 11S. As shown in FIG. 1, the plurality of first structures 11S are arranged along the first direction D1 and the second direction D2.

FIG. 2 shows an enlarged example of a part of the first region 11A. The plurality of first structures 11S are arranged along the first direction D1 at a first pitch p1. The plurality of first structures 11S are arranged along the second direction D2 at a second pitch p2. The first pitch p1 is longer than the second pitch p2.

As shown in FIG. 1, a length of the first region 11A along the first direction D1 is defined as a first length L1. A length of the first region 11A along the second direction D2 is defined as a second length L2. In the embodiment, the first length L1 is longer than the second length L2.

As shown in FIGS. 3A and 3B, the first member 11 may further include a first layered portion 11L. The plurality of first structures 11S are continuous with the first layered portion 11L. The plurality of first structures 11S protrude from the first layered portion 11L. The plurality of first structures 11S include a side face 11SF. The side face 11SF crosses the first plane PL1.

A refractive index of the plurality of first structures 11S is different from the refractive index of the space where the plurality of first structures 11S face each other. The space may be air, etc. The space may be a member different from the first member 11. A difference in refractive indexes is provided on the side face 11SF of the plurality of first structures 11S. The plurality of side faces 11SF act on light incident on the plurality of first structures 11S. The plurality of first structures 11S function as, for example, a photonic crystal layer. The plurality of first structures 11S are, for example, crystals.

For example, light enters the optical element 10A at an arbitrary angle. The light is emitted in a direction including a component perpendicular to the first plane PL1 due to the action of the plurality of first structures 11S. For example, light is difficult to travel in the direction along the first plane PL1. The optical element 10A can, for example, control the direction of light emission.

As described above, in the embodiment, the first pitch p1 is longer than the second pitch p2 in the plurality of first structures 11S. Anisotropy is provided in the pitch of the plurality of first structures 11S. On the other hand, in the first region 11A where the plurality of first structures 11S are provided, the first length L1 is longer than the second length L2. Anisotropy is provided in the shape of the first region 11A. In such a configuration, for example, the anisotropy of the cross-sectional shape of the light acted upon by the optical element 10A can be controlled. For example, the cross-sectional shape of the light beam acted upon by the optical element 10A can be made isotropic, such as circular. Alternatively, the cross-sectional shape can be made close to isotropic, such as circular. According to the embodiment, an optical element whose characteristics can be improved can be provided. Examples of the characteristics of the optical element 10A will be described below.

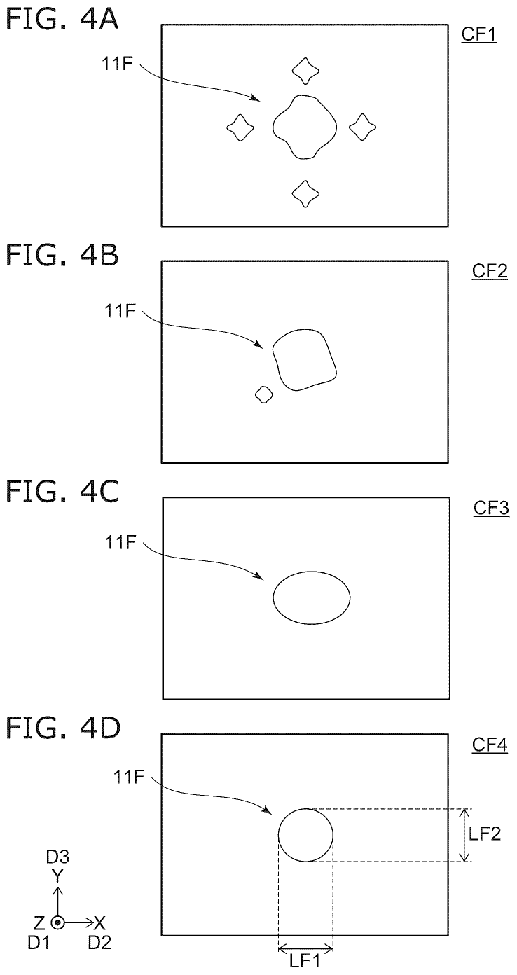

FIGS. 4A to 4D are schematic diagrams illustrating the characteristics of the optical element.

These figures illustrate the far-field pattern 11F of light acted upon by the optical element.

FIG. 4A corresponds to a first configuration CF1. In the first configuration CF1, the cross-sectional shape (planar shape) of one of the plurality of first structures 11S is circular. The first pitch p1 is the same as the second pitch p2. The shape of the first region 11A is a square. In this case, the far-field pattern 11F includes a main pattern and a plurality of sub-patterns around the main pattern. In the first configuration CF1, it is thought that such a far-field pattern 11F occurs due to the influence of interference in a plurality of directions.

FIG. 4B corresponds to a second configuration CF2. In the second configuration CF2, the shape of one of the plurality of first structures 11S is the polygon illustrated in FIG. 2. The first pitch p1 is the same as the second pitch p2. The shape of the first region 11A is a square. Also in this case, the far-field pattern 11F includes a main pattern and a plurality of sub-patterns 10 around the main pattern.

FIG. 4C corresponds to a third configuration CF3. In the third configuration CF3, the shape of one of the plurality of first structures 11S is the polygon illustrated in FIG. 2. The first pitch p1 is longer than the second pitch p2. The shape of the first region 11A is a square. In this case, the far-field pattern 11F includes the main pattern, and the plurality of sub-patterns disappear. In the third configuration CF3, the far-field pattern 11F has an anisotropic shape. In the far-field pattern 11F, the length in the horizontal direction is longer than the length in the vertical direction.

FIG. 4D corresponds to a fourth configuration CF4. In the fourth configuration CF4, the shape of one of the plurality of first structures 11S is the polygon illustrated in FIG. 2. The first pitch p1 is longer than the second pitch p2. In the first region 11A, the first length L1 is longer than the second length L2. For example, the first region 11A has a flat circular shape (see FIG. 1). In this case, the far-field pattern 11F includes the main pattern, and the plurality of sub-patterns disappear. The main pattern is substantially isotropic.

Thus, in the fourth configuration CF4, the cross-sectional shape of the light beam acted upon by the optical element can be made to be an isotropic shape. Alternatively, the cross-sectional shape can be made closer to an isotropic shape. The fourth configuration CF4 corresponds to the embodiment. According to the embodiment, an optical element whose characteristics can be improved can be provided.

For example, the first length L1 may be the maximum length of the first region 11A along the first direction D1. For example, the second length L2 may be the maximum length of the first region 11A along the second direction D2.

As shown in FIG. 1, the first member 11 may further include a second region 11B. The second region 11B is provided around the first region 11A on the first plane PL1. The plurality of first structures 11S are not provided in the second region 11B.

In the embodiment, a ratio of the first pitch p1 to the second pitch p2 is referred to as a first ratio. A ratio of the first length L1 to the second length L2 is defined as a second ratio. The first ratio may be substantially the same as the second ratio. For example, the first ratio may be not less than 0.8 times and not more than 1.2 times the second ratio. As a result, anisotropy can be reduced in the cross-sectional shape of the light beam acted upon by the optical element.

As shown in FIG. 4, the far-field pattern 11F of light acted upon by the optical element 10A includes a first pattern length LF1 along the first direction D1 and a second pattern length LF2 along the second direction D2. A ratio (third ratio) of the first pattern length LF1 to the second pattern length LF2 is lower than the ratio (first ratio) of the first pitch p1 to the second pitch p2. In one example, the third ratio is, for example, not less than 0.8 and not more than 1.2. For example, a substantially isotropic luminous flux is obtained.

In the embodiment, an angle between the first direction D1 and the second direction D2 may be not less than 80 degrees and not more than 100 degrees. The plurality of first structures 11S may be provided in, for example, a rectangular lattice shape.

In the embodiment, at least a part of the outer edge of the first region 11A may be curved. For example, the first region 11A may have a flat circular shape (including an ellipse).

As shown in FIG. 1, the plurality of first structures 11S include a first group G1 arranged along the second direction D2 and a second group G2 arranged along the second direction D2. A direction from the first group G1 to the second group G2 is a direction from the center 11C of the first region 11A to the outside of the first region 11A. The number of the plurality of first structures 11S included in the second group G2 is smaller than the number of the plurality of first structures 11S included in the first group G1.

As shown in FIG. 1, the plurality of first structures 11S include a third group G3 arranged along the first direction D1 and a fourth group G4 arranged along the first direction D1. A direction from the third group G3 to the fourth group G4 is a direction from the center 11C of the first region 11A to the outside of the first region 11A. The number of the plurality of first structures 11S included in the fourth group G4 is smaller than the number of the plurality of first structures 11S included in the third group G3.

The second number of the plurality of first structures 11S arranged along the second direction D2 decreases in a direction from the center 11C of the first region 11A to the outside of the first region 11A along the first direction D1. The first number of the plurality of first structures 11S arranged along the first direction D1 decreases in a direction from the center 11C to the outside along the second direction D2.

In the embodiment, the cross-sectional shape of one of the plurality of first structures 11S along the first plane PL1 may be a circle, a flat circle, or a polygon. The cross-sectional shape of the plurality of first structures 11S can be modified in various ways.

In the embodiment, the cross-sectional shape of the plurality of first structures 11S is more preferably an anisotropic shape. Thereby, it becomes easier to obtain the far-field pattern 11F being more uniform.

In the example shown in FIG. 2, the cross-sectional shape (planar shape) of one of the plurality of first structures 11S is a pentagon with anisotropy. For example, the cross-sectional shape of one of the plurality of first structures 11S along the first plane PL1 is asymmetrical with respect to the first line Ln1 along the first direction D1 and the second line Ln2 along the second direction D2.

In the example shown in FIG. 2, the cross-sectional shape of one of the plurality of first structures 11S includes a first side s1, a second side s2, a third side s3, a fourth side s4, and a fifth side s5. The first side s1 and the third side s3 are along the first direction D1. The second side s2 and the fourth side s4 are along the second direction D2. The fifth side s5 is inclined with respect to the first direction D1 and the second direction D2. A direction from the first side s1 to the third side s3 is along the second direction D2. A direction from the second side s2 to the fourth side s4 is along the first direction D1. The first side s1 connects the second side s2 to the fourth side s4. The third side s3 connects the second side s2 to the fifth side s5. The fourth side s4 connects the first side s1 to the fifth side s5. By such a shape, it becomes easier to obtain a far-field pattern 11F with higher isotropy.

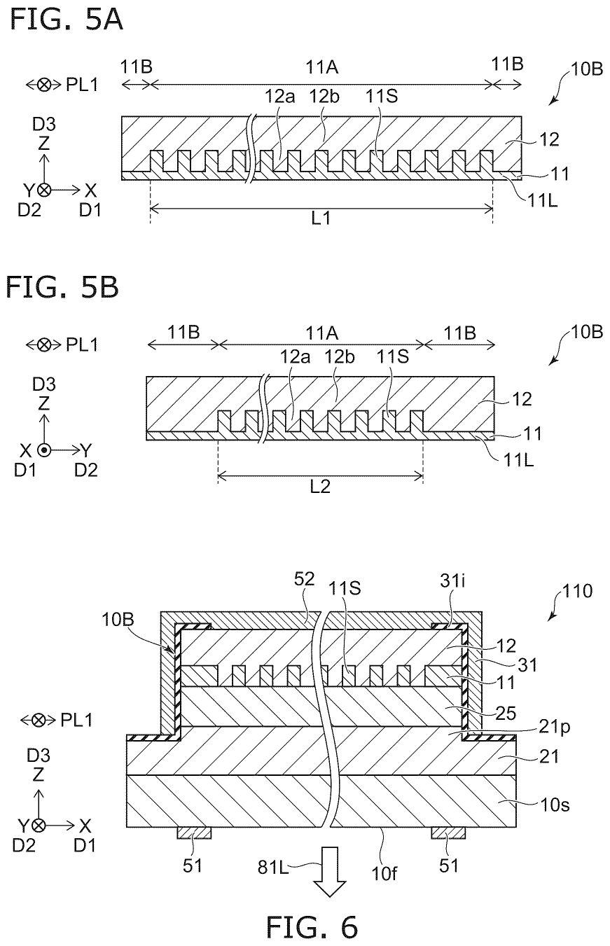

FIGS. 5A and 5B are schematic cross-sectional views illustrating an optical element according to the first embodiment.

FIG. 5A is a cross-sectional view corresponding to the A1-A2 line cross section in FIG. 1. FIG. 5B is a cross-sectional view corresponding to the B1-B2 cross section in FIG. 1.

As shown in FIGS. 5A and 5B, an optical element 10B according to the embodiment includes a second member 12 in addition to the first member 11. The configuration of the optical element 10B except for this may be the same as the configuration of the optical element 10A. For example, also in the optical element 10B, the first pitch p1 is longer than the second pitch p2. The first length L1 is longer than the second length L2.

As shown in FIGS. 5A and 5B, in the optical element 10B, the second member 12 includes a first partial region 12a. The first partial region 12a is provided between the plurality of first structures 11S. The second refractive index of the second member 12 is different from the first refractive index of the first member 11. The first member 11 and the second member 12 form a photonic crystal structure. The optical element 10B can also provide highly isotropic light.

For example, the second member 12 is in contact with the first member 11. The second member 12 may further include a second partial region 12b. A direction from the plurality of first structures 11S to the second partial region 12b is along a third direction D3 crossing the first plane PL1. The third direction D3 is, for example, the Z-axis direction. By providing the second member 12, for example, the shape and characteristics of the first member 11 can be easily maintained stably.

Each of the first member 11 and the second member 12 may include crystals. The crystal lattice of the second member 12 may be continuous with the crystal lattice of the first member 11.

For example, a layer that will become the first member 11 is formed, and the first member 11 is obtained by patterning the layer. The second member 12 is obtained by forming a layer that will become the second member 12 on the first member 11.

In the embodiment, the first pitch p1 is, for example, 1.644 μm. The second pitch p2 is, for example, 1.37 μm. In one example with respect to FIG. 2, the length of the first side s1 is 1.348 μm. The length of the second side s2 is 1.348 μm. The length of the third side s3 is 0.405 μm. The length of the fourth side s4 is, for example, 0.337 μm. In this example, the second side s2 is perpendicular to the first side s1. The fourth side s4 is perpendicular to the first side s1. The third side s3 is perpendicular to the second side s2. These values are examples, and various modifications are possible.

### Second Embodiment

FIG. 6 is a schematic cross-sectional view illustrating a surface emitting laser according to a second embodiment.

As shown in FIG. 6, a surface emitting laser 110 according to the embodiment includes the optical element 10B according to the first embodiment, a first electrode 51, a second electrode 52, a first cladding layer 21, and a light emitting layer 25. The first cladding layer 21 is provided between the first electrode 51 and the second electrode 52. The light emitting layer 25 is provided between a part 21p of the first cladding layer 21 and the second electrode 52. The optical element 10B is provided between the light emitting layer 25 and the second electrode 52. The first member 11 is provided between the light emitting layer 25 and the second member 12. The second refractive index is lower than the first refractive index.

In the surface emitting laser 110, the second member 12 may function as a second cladding layer.

In the surface emitting laser 110, light is emitted from the light emitting layer 25 by a current supplied between the first electrode 51 and the second electrode 52. The traveling direction of the light is controlled in the optical element 10B, and the light is emitted to the outside via the first cladding layer 21. The output light 81L from the surface emitting laser 110 includes a component along the Z-axis direction. Planar output light 81L is emitted.

As shown in FIG. 6, the surface emitting laser 110 may include a substrate 10s. The first cladding layer 21 is provided between the substrate 10s and the light emitting layer 25. The output light 81L is emitted from the substrate surface 10f of the substrate 10s.

For example, the light emitting layer 25 emits light due to inter-subband transition. The surface emitting laser 110 may be, for example, a surface emitting quantum cascade laser (QCL).

When the light emitting layer 25 has substantially a single wavelength, the far-field pattern 11F described with reference to FIGS. 4A to 4D occurs. For example, when a quantum cascade laser or the like is combined with a photonic crystal layer, the sub-patterns described with respect to FIGS. 4A and 4B occur. By applying the optical element 10B according to the embodiment, isotropic light is easily obtained in the surface emitting laser 110.

The surface emitting laser 110 may be applied to, for example, an analysis device. In an analysis device or the like, the traveling direction of the light beam is controlled by a mirror or the like. For example, light scanning is performed. In such an example, if the cross section of the light beam has an anisotropic shape, it is not easy to control the traveling direction while maintaining the desired shape of the light beam. In the embodiment, the cross-sectional shape of the output light 81L from the surface emitting laser 110 is highly isotropic. Thereby, it becomes easy to maintain the desired light beam characteristics even when the traveling direction is controlled using a mirror or the like. According to the embodiment, a surface emitting laser whose characteristics can be improved can be provided.

As shown in FIG. 6, the surface emitting laser 110 may further include a reflective film 31. A direction from the light emitting layer 25 to the reflective film 31 is along the first plane PL1. The reflectance of the reflective film 31 at the wavelength of light emitted from the light emitting layer 25 is higher than the reflectance of the first cladding layer 21 at that wavelength. The reflectance of the reflective film 31 at the wavelength of light emitted from the light emitting layer 25 is higher than the reflectance of the second member 12 (second cladding layer) at the wavelength. The reflective film 31 may be continuous with the second electrode 52.

As shown in FIG. 6, the surface emitting laser 110 may further include an insulating film 31i. At least a part of the insulating film 31i is provided between the light emitting layer 25 and the reflective film 31.

In one example, the first member 11 includes In, Ga, and As. The second member 12 includes In and P. The first cladding layer 21 includes In and P.

As described with reference to FIG. 4D, the far-field pattern 11F of the light emitted through the first cladding layer 21 includes the first pattern length LF1 along the first direction D1 and the second pattern length LF2 along the second direction D2. A ratio of the first pattern length LF1 to the second pattern length LF2 is lower than a ratio of the first pitch p1 to the second pitch p2.

In the surface emitting laser 110, an angle between the first direction D1 and the second direction D2 may be not less than 80 degrees and not more than 100 degrees. The angle may be not less than 85 degrees and not more than 90 degrees.

The Embodiments may include the following Technical proposals:

### Technical Proposal 1

An optical element, comprising:
a first member including a first region along a first plane,
the first region including a plurality of first structures,
the plurality of first structures being arranged along a first direction at a first pitch and along a second direction at a second pitch,
the first direction being along the first plane,
the second direction being along the first plane and crossing the first direction,
the first pitch being longer than the second pitch, and
a first length of the first region along the first direction being longer than a second length of the first region along the second direction.

### Technical Proposal 2

The optical element according to Technical proposal 1, wherein
the first member further includes a second region,
the second region is provided around the first region in the first plane, and
the plurality of first structures are not provided in the second region.

### Technical Proposal 3

The optical element according to Technical proposal 1 or 2, wherein
a first ratio of the first pitch to the second pitch is not less than 0.8 times and not more than 1.2 times a second ratio of the first length to the second length.

### Technical Proposal 4

The optical element according to any one of Technical proposals 1-3, wherein
a cross-sectional shape of one of the plurality of first structures along the first plane is a circle, a flat circle, or a polygon.

### Technical Proposal 5

The optical element according to any one of Technical proposals 1-3, wherein
a cross-sectional shape of one of the plurality of first structures along the first plane is asymmetrical with respect to a first line along the first direction and a second line along the second direction.

### Technical Proposal 6

The optical element according to any one of Technical proposals 1-5, wherein
the plurality of first structures are crystals.

### Technical Proposal 7

The optical element according to any one of Technical proposals 1-6, wherein
the first member is at least a part of a photonic crystal.

### Technical Proposal 8

The optical element according to any one of Technical proposals 1-7, wherein
a second number of the plurality of first structures arranged along the second direction decreases along a direction from a center of the first region to an outside of the first region along the first direction, and
a first number of the plurality of first structures arranged along the first direction decreases in a direction from the center to the outside along the second direction.

### Technical Proposal 9

The optical element according to any one of Technical proposals 1-7, wherein
the plurality of first structures include a first group arranged along the second direction and a second group arranged along the second direction,
a direction from the first group to the second group is from a center of the first region to an outside of the first region, and
a number of the plurality of first structures included in the second group is smaller than a number of the plurality of first structures included in the first group.

### Technical Proposal 10

The optical element according to any one of Technical proposals 1-9, wherein
at least a part of an outer edge of the first region is curved.

### Technical Proposal 11

The optical element according to any one of Technical proposals 1-10, further comprising:
a second member including a first partial region,
the first partial region being provided between the plurality of first structures, and
a second refractive index of the second member being different from a first refractive index of the first member.

### Technical Proposal 12

The optical element according to Technical proposal 11, wherein
the second member is in contact with the first member.

### Technical Proposal 13

The optical element according to Technical proposal 11 or 12, wherein
the second member further includes a second partial region, and
a direction from the plurality of first structures to the second partial region is along a third direction crossing the first plane.

### Technical Proposal 14

A surface emitting laser, comprising:
the optical element according to any one of Technical proposals 11-13;
a first electrode;
a second electrode;
a first cladding layer provided between the first electrode and the second electrode; and
a light emitting layer provided between a part of the first cladding layer and the second electrode,
the optical element being provided between the light emitting layer and the second electrode,
the first member being provided between the light emitting layer and the second member, and
the second refractive index is lower than the first refractive index.

### Technical Proposal 15

The surface emitting laser according to Technical proposal 14, further comprising:
a reflective film,
a direction from the light emitting layer to the reflective film being along the first plane,
a reflectance of the reflective film at a wavelength of light emitted from the light emitting layer being higher than a reflectance of the first cladding layer at the wavelength.

### Technical Proposal 16

The surface emitting laser according to Technical proposal 15, further comprising:
an insulating film provided between the light emitting layer and the reflective film.

### Technical Proposal 17

The surface emitting laser according to any one of Technical proposals 14-16, further comprising:
the light-emitting layer emits light by inter-subband transition.

### Technical Proposal 18

The surface emitting laser according to any one of Technical proposals 14-17, wherein
the first member includes In, Ga and As,
the second member includes In and P, and
the first cladding layer includes In and P.

### Technical Proposal 19

The surface emitting laser according to any one of Technical proposals 14-18, wherein
a far-field pattern of light passing through the first cladding layer and being emitted includes a first pattern length along the first direction and a second pattern length along the second direction, and
a ratio of the first pattern length to the second pattern length is lower than a ratio of the first pitch to the second pitch.

### Technical Proposal 20

The surface emitting laser according to any one of Technical proposals 14-19, wherein
an angle between the first direction and the second direction is not less than 80 degrees and not more than 100 degrees.

According to the embodiment, an optical element and a surface emitting laser whose characteristics can be improved can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in optical elements and surface emitting lasers such as members, electrodes, cladding layers, light emitting layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all optical elements and surface emitting lasers practicable by an appropriate design modification by one skilled in the art based on the optical elements and the surface emitting lasers described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An optical element, comprising:
a first member including a first region along a first plane,
the first region including a plurality of first structures,
the plurality of first structures being arranged along a first direction at a first pitch and along a second direction at a second pitch,
the first direction being along the first plane,
the second direction being along the first plane and crossing the first direction,
the first pitch being longer than the second pitch, and
a first length of the first region along the first direction being longer than a second length of the first region along the second direction.

2. The optical element according to claim 1, wherein
the first member further includes a second region,
the second region is provided around the first region in the first plane, and
the plurality of first structures are not provided in the second region.

3. The optical element according to claim 1, wherein
a first ratio of the first pitch to the second pitch is not less than 0.8 times and not more than 1.2 times a second ratio of the first length to the second length.

4. The optical element according to claim 1, wherein
a cross-sectional shape of one of the plurality of first structures along the first plane is a circle, a flat circle, or a polygon.

5. The optical element according to claim 1, wherein
a cross-sectional shape of one of the plurality of first structures along the first plane is asymmetrical with respect to a first line along the first direction and a second line along the second direction.

6. The optical element according to claim 1, wherein
the plurality of first structures are crystals.

7. The optical element according to claim 1, wherein
the first member is at least a part of a photonic crystal.

8. The optical element according to claim 1, wherein
a second number of the plurality of first structures arranged along the second direction decreases along a direction from a center of the first region to an outside of the first region along the first direction, and
a first number of the plurality of first structures arranged along the first direction decreases in a direction from the center to the outside along the second direction.

9. The optical element according to claim 1, wherein
the plurality of first structures include a first group arranged along the second direction and a second group arranged along the second direction,
a direction from the first group to the second group is from a center of the first region to an outside of the first region, and
a number of the plurality of first structures included in the second group is smaller than a number of the plurality of first structures included in the first group.

10. The optical element according to claim 1, wherein
at least a part of an outer edge of the first region is curved.

11. The optical element according to claim 1, further comprising:
a second member including a first partial region,
the first partial region being provided between the plurality of first structures, and
a second refractive index of the second member being different from a first refractive index of the first member.

12. The optical element according to claim 11, wherein
the second member is in contact with the first member.

13. The optical element according to claim 11, wherein
the second member further includes a second partial region, and
a direction from the plurality of first structures to the second partial region is along a third direction crossing the first plane.

14. A surface emitting laser, comprising:
the optical element according to claim 11;
a first electrode;
a second electrode;
a first cladding layer provided between the first electrode and the second electrode; and
a light emitting layer provided between a part of the first cladding layer and the second electrode,
the optical element being provided between the light emitting layer and the second electrode,
the first member being provided between the light emitting layer and the second member, and
the second refractive index is lower than the first refractive index.

15. The surface emitting laser according to claim 14, further comprising:
a reflective film,
a direction from the light emitting layer to the reflective film being along the first plane,
a reflectance of the reflective film at a wavelength of light emitted from the light emitting layer being higher than a reflectance of the first cladding layer at the wavelength.

16. The surface emitting laser according to claim 15, further comprising:
an insulating film provided between the light emitting layer and the reflective film.

17. The surface emitting laser according to claim 14, further comprising:
the light-emitting layer emits light by inter-subband transition.

18. The surface emitting laser according to claim 14, wherein
the first member includes In, Ga and As,
the second member includes In and P, and
the first cladding layer includes In and P.

19. The surface emitting laser according to claim 14, wherein
a far-field pattern of light passing through the first cladding layer and being emitted includes a first pattern length along the first direction and a second pattern length along the second direction, and
a ratio of the first pattern length to the second pattern length is lower than a ratio of the first pitch to the second pitch.

20. The surface emitting laser according to claim 14, wherein
an angle between the first direction and the second direction is not less than 80 degrees and not more than 100 degrees.
